(19) United States
(12) Patent Application Publication
(10) Pub. No.: US 2012/0060901 A1
(43) Pub. Date: Mar. 15, 2012

(54) Profile rail, support element and solar module arrangement formed therewith, in particular for transversal mounting of solar modules

(75) Inventor: Sandy Schnitzer, Feldberger Seenlandschaft (DE)

(73) Assignee: Mounting Systems GmbH, Rangsdorf (DE)

(21) Appl. No.: 13/199,547

(22) Filed: Aug. 31, 2011

(30) Foreign Application Priority Data
Sep. 1, 2010 (DE) 10 2010 040 124.2

(51) Int. Cl. H01L 31/048; H01L 23/12

(52) U.S. Cl. 136/251; 211/41.1

(57) ABSTRACT

The invention relates to a profile rail in particular for supporting framed solar modules, including a rail element and two support arms, wherein at least one of the support arms protrudes from the rail element in a transversal direction (q) that is perpendicular to a longitudinal orientation of the profile rail, and wherein the support arms include support surfaces that are parallel to one another are at different elevations with respect to a lower edge of the profile rail with an elevation offset from one another in an elevation direction perpendicular to the transversal and longitudinal direction, and a support surface oriented in the transversal direction and arranged between the support arms, wherein the support surface bridges the elevation difference between the support arms at least partially.

### CROSS REFERENCE TO RELATED APPLICATION

Reference is made to and priority claimed from German Patent Application Serial No. DE 10 2010 040 124.2, filed Sep. 1, 2010, entitled PROFILSCHIENE, HALTEELEMENT UND DAMIT GEBILDETE SOLARMODULANORDNUNG, INSBESONDERE FÜR EINE QUERMONTAGE VON SOLARMODULEN.

### BACKGROUND OF THE INVENTION

1. Technical Field

The invention relates to a profile rail, in particular for supporting framed solar modules, a support element for a frame for use in combination with a profile rail according to the invention and a solar module arrangement.

2. Discussion of Related Art

From the document EP 2 006 613 A2 a solar module arrangement with profile rails and support elements for supporting framed solar modules on a roof is known. A frame assembly is mounted to the tilted roof surface of the slanted roof. Two horizontal profile rails, thus extending parallel to the roof ridge are attached to two additional rails of the frame that extend perpendicular thereto. The rectangular solar modules contact the two horizontal profile rails with the shorter transversal sides of their frames. A gallows shaped support component is configured at the one piece horizontal profile rails, wherein the support component forms a support surface for supporting the solar module with one side of its vertical portion. T-shaped support plates are inserted between the two solar modules into the horizontally extending profile rails in order to support two adjacent solar modules in one direction perpendicular to the roof surface like the horizontal component of the gallows shaped support component of the profile rail. The support elements reach about the adjacent solar module frames respectively on the longer frame longitudinal sides.

The technical problem to be solved by the invention is to provide a configuration for supporting framed solar modules for a solar module plant, wherein the configuration can be produced and mounted in a simpler manner. It is desirable that this configuration is also configured for mounting rectangular solar modules in a transversal direction.

### DISCLOSURE OF INVENTION

Subsequently the different features of the invention and preferred embodiments of a solar module arrangement are described. Eventually the advantages and embodiments of various features of the invention are described.

In one embodiment of the invention, the technical problem is solved through a profile rail in particular for supporting framed solar modules including
a rail element, which may also be referred to as a rail body,
two support arms, wherein at least one of the support arms protrudes from the rail element in a transversal direction that is perpendicular to a longitudinal orientation of the profile rail and the support surfaces that are parallel to one another are at different levels with respect to a lower edge of the profile rail with an elevation offset from one another in an elevation direction perpendicular to the transversal and longitudinal direction, and
a support surface oriented in the transversal direction and disposed between the support arms, wherein the support surface bridges the elevation difference between the support arms.

According to a second embodiment of the invention, a support element for a frame is provided for a use in combination with a profile rail according to the first embodiment of the invention or one of its embodiments including
a frame receiver that is T shaped in a cross-sectional view, wherein a vertical beam of the T-shape forms a support surface for a frame to be supported in installed condition,
an arm receiver that is C shaped in the same cross-sectional view and connected with the frame receiver and configured to reach in installed condition about a support arm of the profile rail that protrudes from the profile rail in a transversal direction from the rail element perpendicular to the longitudinal direction of the profile rail, wherein an outer surface of the upper C-beam of the arm receiver simultaneously forms a frame support surface of the frame receiver.

A third preferred embodiment of the invention is provided by a solar module arrangement, including
a plurality of profile rails extending parallel to one another and offset from one another transversal to their longitudinal direction according to the first embodiment of the invention or another embodiment;
a plurality of framed solar modules which are respectively supported on two adjacent profile rails,
wherein the solar modules are respectively supported with a first frame component of their frame in the frame receiver of at least one of the support elements according to the second embodiment of the invention or one of its embodiments on a first support arm of a first of the two adjacent profile rails and directly contact a second support arm of a second of the two adjacent profile rails with another frame component, wherein the second support arm is oriented towards the first profile rail.

The solution according to the invention has advantages over the known art with respect to assembly and also with respect to fabrication. In combination with one another the profile rail according to the first aspect of the invention and the support element according to the second aspect of the invention facilitate mounting solar modules in a particularly simple manner with a minimum of additional fasteners like bolts etc. This is facilitated in that one the one hand side the support of the solar modules is facilitated on a first profile rail in the frame receiver of the support elements and on the other hand side the direct contact of the solar modules on a support arm of an adjacent profile rail is facilitated. A sliding of the solar module frames against the transversal direction due to gravity is prevented through the support surface between the support arms which partially or completely bridges the elevation distance between the support arms. Simultaneously it is prevented through the support of the solar module frames in the C shaped frame receiver of the support element in combination with the C shaped arm receiver that the frame lifts off from the profile rail in elevation direction (suction safety). Eventually a sliding in longitudinal direction of the profile rail is prevented due to the frictional force between the support element and the support surface of the profile rail. Thus it is achieved through the configuration of profile rail and support element according to the invention to facilitate a fixed support for the solar modules based on form-locking and friction-locking.

A separate attachment of the support elements on the profile rails is not required as a matter of principle. Only on the uppermost profile rail an additional attachment of the support element is helpful against sliding in transversal direction which is achieved e.g. through bolts in preferred simple embodiments, wherein the bolts attach the support elements at the rail element of the profile rail.

From a production point of view, the advantage of the solution according to the invention is that the support elements only have to be cut out from a simple profile that is fabricated accordingly and do not require any additional finishing or preassembly besides preparing additional attachment means at the upper profile rail which were recited supra.

Subsequently embodiments of the various features of the inventions are described. The additional features of the embodiments can be combined with one another as long as they are not described as being alternatives to one another.

A particular preferred embodiment of the support element provides that an upper horizontal beam of the C shaped arm receiver forms a support surface for the frame to be supported in installed condition and that the upper horizontal C-beam has a material thickness in elevation direction which is identical with the elevation offset of the support surface of the profile rail. This facilitates that all solar modules can be arranged in a common plane in installed condition. Thus, preferably in the solar module arrangement the profile rails are mounted so that their support surfaces with identical height with respect to the respective profile rail are respectively arranged in a common plane. By using the support elements according to the present embodiment which are engaged in the solar module assembly in the profile rails respectively on support arms with small elevation it is achieved that the common plane for supporting the frames includes the support surfaces of the upper support arms and the frame support surfaces of the support elements. This common plane thus corresponds to the common plane formed by the support surfaces with greater height on the profile rails.

A configuration of the profile rail that is particularly simple to manufacture has support surfaces that are adjacent to one another like steps, wherein the support surfaces are connected through the support surface oriented in transversal direction. Preferably the support surfaces and the support surface of the profile rail extend in its longitudinal direction over the entire length of the profile rail.

Both support arms of the profile rail protrude in preferred embodiments from the rail element since this forms a configuration that is stable and saves material at the same time. However, It is also feasible to have only one of the two support arms protrude from the rail element and to configure the other of the two support arms completely on a top-side of the rail element. In this case preferably the one of the two support arms protrudes which has the lower height above the lower edge of the profile rail. The support element is arranged thereon.

The one of the two support arms whose support surface is arranged in elevation direction at the lower elevation in one embodiment includes at its bottom side a connection element for form-locking connection of the profile rail with a support element. The form-locked connection is used for securing the position of the frame supported on the lower one of the two support arms. The form-locking connection is configured so that pulling the support element off from the profile rail is impeded or prevented in a direction in which the support arm protrudes from the rail element. The connection element can be configured e.g. as a downward protruding lug which is configured to engage an accordingly formed mating connection element of the support element. This way a snap-locking mechanism for safe mounting of the module is provided which cannot fly off during assembly. Also an alternative form of the connection element configured as a recess either at the profile rail or at the support element is conceivable, wherein a protruding connection element like a lug or a tooth engages at the respective other component for establishing the form-locked connection.

The basic function of the basic configuration of the support element can be improved in a particular manner for different installation locations within a solar module assembly.

For supporting the solar module in particular on a lowest profile rail of the solar module assembly in particular C shaped receivers are suitable. This support element facilitates an effective support of the solar modules against sliding in transversal direction of the profile rail in a simple manner using form-locking configuration features. It is appreciated that depending on the viewing direction a C-shape like the letter C or a mirror image thereof can appear. The “actual C-shape” and the C-shape mirrored at the vertical beam are equivalent embodiments of the C-shape in this respect. Forming a frame receiver through the C-shape, thus an opening of the form oriented towards the frame is essential.

This applies accordingly to the C-shape of the arm receiver. Herein the viewing direction towards the support element is less important than the opening of the arm receiver towards the support arm in order to be able to reach around the support arm on three sides. In the support element with C-shaped frame receiver the support surfaces of the frame receiver and of the arm receiver and thus their openings are oriented in different directions.

The arm receiver includes an opposite connection element for form locking connection of the profile rail with the support element in an embodiment on its side of the lower horizontal C-beam that is oriented inward, that means oriented towards the support arm of the profile rail in assembled condition. The purpose and possible configurations of the opposite connection element were already described supra in connection with the respective embodiment of the profile rail. Thus, the opposite connection element can be configured e.g. as an upward protruding lug with which a respectively configured downward protruding connection element of the profile rail can come into engagement. A recess is also conceivable as an alternative shape for the opposite connection element.

The C-shape of the frame receiver of the support element is exactly adapted to the dimensions of the frame to be received with the inner dimensions of the support element, besides having a necessary clearance. Thus, the upper horizontal C-beam of the frame receiver prevents that the supported solar module only slightly lifts off under wind influence. This function is supported by the arm receiver which is also C-shaped and prevents a lift off of the solar module together with the support element from the profile rail.

For the upper most profile rail also a simplified support element is suitable which includes a frame receiver which has the shape of a Greek capital letter gamma or of a gallows. The support element in the present embodiment for use in the upper most profile rail does not have to perform any support function against downward sliding but only has to prevent a movement of the solar module frames in transversal direction of the profile rail upward in the longitudinal direction of the profile rail and a lift off in elevation direction. This is achieved in a very simple manner through a shape in which all the support surfaces of the frame receiver and of the arm receiver are oriented in the same direction.

The support element for an application in the upper most profile rail preferably includes an attachment arm that is connected in a perpendicular manner at the lower horizontal C-arm of the arm receiver. The attachment arm can be used for attaching the support element against movements in transversal direction of the profile rail and includes as recited supra e.g. a bore hole for receiving a connection device e.g. a bolt. The connection device can be used for attaching the support element at the rail element of the profile rail, wherein the profile rail can be provided with a thread at a corresponding location. For simplicity purposes self tapping screws can certainly also be used so that the necessity of a thread in the wall of the profile rail does not exist anymore.

For installing solar modules on all other profile rails, this means besides the lower most and the upper most profile rail, support elements with the T-shaped frame receiver are suited in particular, wherein the vertical T-beam forms a support surface for one respective beam on both its sides. With a support element of this type the support functions described supra of the support elements on the lower most and upper most profile rail are combined in an effective manner without requiring a separate attachment on the profile rail.

The solution according to the invention of combining the profile rail with support elements is suitable for a longitudinal assembly and also for a transversal assembly of solar modules.

Additional embodiments are described in the appended dependent claims.

### BRIEF DESCRIPTION OF THE DRAWINGS

A preferred embodiment of the invention is described infra with reference to appended drawing figures wherein:

FIG. 1 illustrates a solar module arrangement in a perspective cross section view; and

FIG. 2 illustrates a detail view of a variant of the solar module arrangement of FIG. 1.

### DETAILED DESCRIPTION

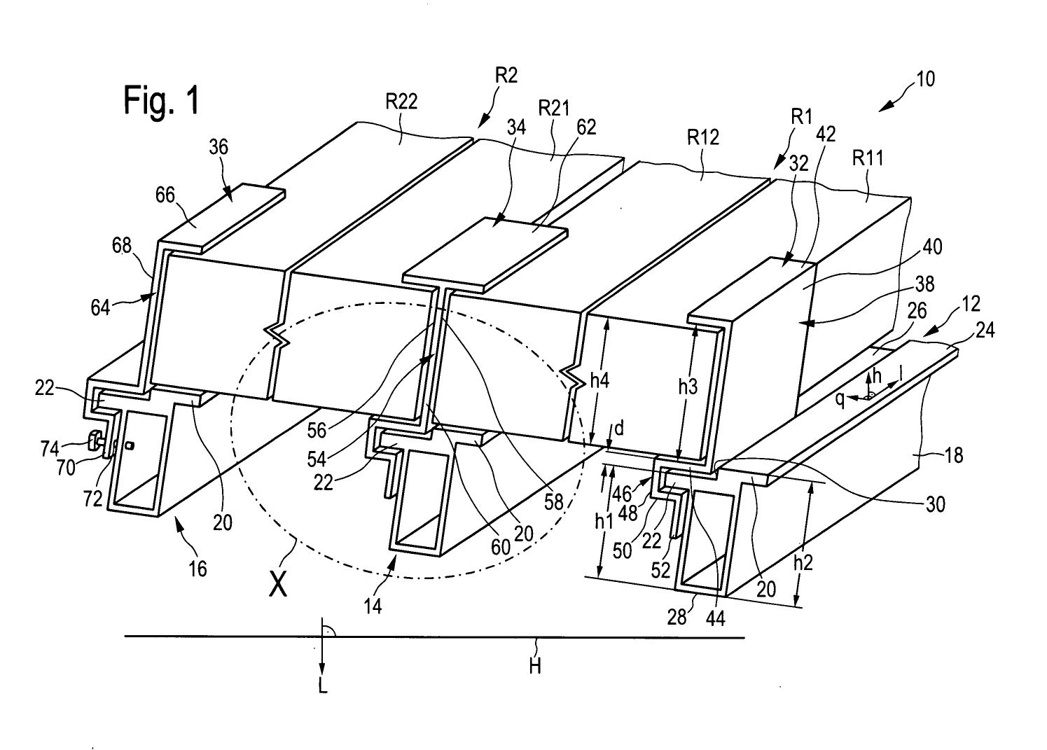

The solar module arrangement 10 of FIG. 1 is only illustrated in a schematic manner. In particular the solar modules are only schematically indicated through frame portions R11 and R12 of a first frame R1 and frame portions R21 and R22 of a second frame R2.

The solar module arrangement 10 includes a number of profile rails of which the profile rails, 12, 14 and 16 are illustrated in FIG. 1. Details regarding the mounting of the profile rails on a frame are not illustrated herein and are known in the art. A coordinate system illustrates a longitudinal direction I, a transversal direction q and an elevation direction h respectively with respect to the profile rail 12. Depending on the orientation of the profile rail the elevation direction h can be inclined relative to a vertical direction L oriented towards the earth center.

Typically the solar module arrangement is installed at a slant angle. This can be put differently in that the common plane of the solar modules is inclined relative a horizontal plane H at the installation location of the solar module arrangement 10, thus it is arranged at an acute angle to this plane. The horizontal plane (H) is presumed independent from the properties of the installation location as being perpendicular to the vertical direction L at the installation location. The arrangement of FIG. 1 is configured so that the profile rail 12 is the lowest profile rail, thus the profile rail of the solar module arrangement that is most proximal to a theoretically horizontal plane H and the profile rail 16 is the upper most profile rail, thus the farthest away from the horizontal plane H. A roof installation and also an installation in a free standing solar plant are feasible with the present solar module arrangement when using suitable additional installation devices.

The profile rails 12, 14, and 16 are substantially identical. They include a rail element 18 which is presently configured from a rectangular hollow profile. Two support arms 20 and 22 protrude from the rail element 18. The support arms 20, 22 form support surfaces 24 and 26 on their upper sides at different elevations h1 and h2 relative to a lower edge 28 of the profile rail 12. The elevation distance or elevation difference between the two support surfaces 24 and 26 is designated with d in FIG. 1, wherein

d=h2−h1 applies.

The elevation distance d is bridged through a support surface 30 which is oriented in the transversal direction q. This way the two support arms 20 and 22 with their support surfaces 24 and 26 are configured adjacent to one another in a step configuration.

At the step, thus the support surface 30 support elements are respectively in contact, wherein FIG. 1 illustrates the support elements 32, 34 and 36. It is appreciated that plural at least two support element per solar module are provided over the length of the profile rails 12, 14 and 16.

The basic configuration of the support elements is subsequently described with reference to the support element 32 which is provided for installation on the lowest profile rail 12. The support element 32 includes a frame receiver 38. The frame receiver 38 is C-shaped in the cross sectional view of FIG. 1. More precisely the frame receiver in the selected view has a shape of a “C” that is mirrored at its vertical wall 40. An elevation offset h3 between the upper and lower horizontal C-beam 42, 44 is selected according to an elevation dimension h4 of a frame R1 of a solar module. The elevation offset h3 is preferably configured with a clearance, thus slightly larger than the elevation dimension h4 of the frame in order to facilitate inserting and slightly moving the frame in longitudinal direction of the profile rail 12. The rear wall 40 of the C-shaped frame receiver 38 contacts a support surface 30 of the profile rail 12 with its lower section.

With a C-shaped arm receiver 46 which includes horizontal C-beams 44 and 50 and a vertical C-beam 48 the support element 32 reaches around the support arm 22. The upper horizontal beam of the C-shaped arm receiver is identical with the lower horizontal C-beam 44 of the frame receiver.

Thus, in installed condition the frame R on the one hand side presses the support element 32 against the support surface 30 and on the other hand side onto the lower support surface 26. Thus, on the one hand side form locking prevents a sliding of the frame in downward direction, thus due to gravity against the transversal direction q. On the other hand side friction locking between the support element 32 and the support surface 26 prevents a sliding of the frame in longitudinal direction of the profile rail. A lift off of the frame in the elevation direction h is prevented by the C-shape of the frame receiver 38 and through the C-shape of the arm receiver 46. Thus a separate attachment of the support element 32 at the rail element 18 is not required. It is sufficient to engage the support element 32 in the profile rail at the lower receiving arm 22 and to subsequently insert the frame R.

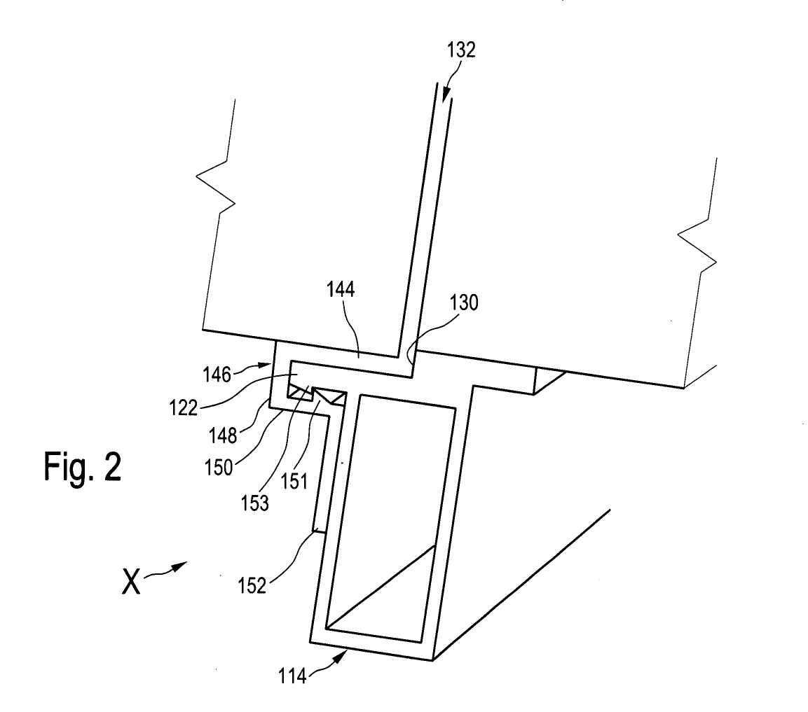

Reference is made to the preferred embodiment illustrated in FIG. 2 and including an additional safety for the connection between the support element and the profile rail. The detail illustrated in FIG. 2 approximately corresponds to the portion X illustrated in FIG. 1 through a dash dotted line. The reference numerals used in FIG. 2 for components that are also illustrated in FIG. 1 are identical to the reference numerals used in FIG. 1, however they additionally include a preceding 1. For example the profile rail in FIG. 1 is characterized by the reference numeral 14 and in FIG. 2 it is characterized by the reference numeral 114.

The variant of FIG. 2 provides an additional form locking connection between the profile rail 114 and the support element 132. Thus, the support arm 122 whose support surface is arranged at a lower level in elevation direction includes a connection element 153 configured as a lug at its bottom. As an opposite connection element the support element also includes a lug 151 which however is oriented in upward direction at the arm receiver 146 at its inward oriented side, this means in assembly condition oriented towards the support arm 122 of the profile rail 114 of the lower horizontal C-beam 150. During assembly the form locking connection can be established through simply “clicking in” the support element 132 and when required the support element can be disengaged through elastic bending. Through this connection the support element 132 can already be secured during assembly against sliding from a direction that is perpendicular to the longitudinal direction of the profile rail 114 and to the support surfaces of the support arm and the module can be safely mounted.

Subsequently reference is made to FIG. 1 again. It is appreciated that the lower horizontal beam of the C-shaped frame receiver 38 in a particularly preferred embodiment has a material thickness h in elevation direction which is exactly identical with the elevation offset d of the support surfaces 24 and 26. This way it is facilitated that the inserted solar module with its frame R1 is exactly in the same frame as the adjacent frame R2. Overall this way all solar modules are supported in the same common plane.

The support elements 34 and 36 differ from the support element 32 in some details which are described infra. The support element 34 includes a T-shaped frame receiver 54 with two support surfaces 56 and 58. The support surface 56 is used for supporting a second solar module R2. Furthermore the horizontal T-beam 62 of the frame receiver 54 of the support element 34 is used for supporting the frames R1 and R2 on both sides against movements in elevation direction h, in particular as a suction safety.

The support element 36 includes an S-shaped frame receiver 64 at the upper most profile rail 16. Herein, however, the frame contacts the higher support arm 20 directly with the bottom side of the frame. The support element 36 in its frame receiver includes an upper horizontal beam 66 and a vertical beam 68. These beams prevent movements of the installed solar module frame R2 in elevation direction and in transversal direction. A bore hole 72 is provided at an attachment arm 70 for fixating the support element in transversal direction, wherein the bore hole prevents a sliding of the support element 36 in transversal direction through a bolt 74.

The assembly of a solar module arrangement is advantageously performed from the bottom to the top, thus it starts with installing the support elements 32 on the lowest profile rail and the support elements 34 on the next adjacent profile rail 14. After outfitting the two profile rails 12 and 14 with a first solar module row the next higher solar module row is mounted up to the upper most solar module row between the profile rail 14 and 16. Eventually the support elements are bolted down at the upper most profile rail 16 with the bolts 74.

It is appreciated that the technical problem and the solution according to the invention are independent from solar modules or other frame components like e.g. LED modules being mounted.

What is claimed is:

1. A profile rail (12, 14, 16) in particular for supporting framed solar modules, comprising:
a rail element (18);
two support arms (20, 22),
wherein at least one of the support arms protrudes from the rail element (18) in a transversal direction (q) that is perpendicular to a longitudinal orientation (L) of the profile rail, and
wherein the support arms include support surfaces (24, 26) that are parallel to one another are at different elevations (h1, h2) with respect to a lower edge (28) of the profile rail (12, 14, 16) with an elevation offset (d) from one another in an elevation direction (h) perpendicular to the transversal and longitudinal direction; and
a support surface (30) oriented in the transversal direction (q) and arranged between the support arms (20, 22), wherein the support surface bridges the elevation difference between the support arms at least partially.

2. The profile rail (12, 14, 16) according to claim 1, in which the support arms (20, 22) are adjacent to one another in steps and the support surface (30) connects the support surfaces (24, 26).

3. The profile rail (114) according to claim 2, wherein the support arm (122) of the two support arms whose support surface is arranged in elevation direction at a lower elevation includes a connection element (153) at its bottom side for form locking connection of the profile rail with a support element (132).

4. The profile rail (12, 14, 16) according to claim 1, wherein both support arms (20, 22) protrude from the profile rail in transversal direction (q).

5. A support element (32, 34, 36) for a frame for a use in combination with a profile rail according to claim 1, comprising
a frame receiver (38) that is T shaped in a cross-sectional view, wherein a vertical beam (40) of the T-shape forms a support surface for a frame (R1) to be supported in installed condition;
an arm receiver (46) that is C shaped in the same cross-sectional view and connected with the frame receiver (38) and configured to reach in installed condition about a support arm (22) of the profile rail (12) that protrudes from the rail element (18) in a transversal direction (q) that is perpendicular to the longitudinal direction (L) of the profile rail, wherein an outer surface of the upper C-beam of the arm receiver (46) simultaneously forms a frame support surface of the frame receiver.

6. The support element (34) according to claim 5, wherein a vertical T-beam (62) of the frame receiver forms respective support surfaces (56, 58) on both its sides for respective frames (R1, R2).

7. The support element (32, 34, 36) according to claim 5, in which an upper horizontal C-beam (44) of the C-shaped arm receiver (46) forms a support surface for the frame to be supported in installed condition and in which the upper horizontal C-beam of the arm receiver has a material thickness (d) in elevation direction (h) which is identical with an elevation offset (h1, h2, d) of the support surfaces 24, 26 of the profile rail.

8. A solar module arrangement, comprising:
a plurality of profile rails (12, 14, 16) extending parallel to one another and offset from one another transversal to their longitudinal direction according to claim 1;
a plurality of framed solar modules (R1, R2) which are respectively supported on two adjacent profile rails (12, 14; 14, 16),
wherein the solar modules are respectively supported with a first frame component of their frame in the frame receiver (38) of at least one of the support elements (32, 34, 36) on a first support arm (22) of a first profile rail (12) of the two adjacent profile rails (12, 14) and contact with another frame component directly a second support arm (20) of a second profile rail (14) of the two adjacent profile rails, wherein the second support (20) arm is oriented towards the first profile rail (12) and wherein both support arms (20, 22) protrude from the profile rail in transversal direction (q).

9. The solar module arrangement according to claim 8, wherein support arms (20, 22) of the adjacent profile rails (12, 14) include support surfaces at different elevations (h1, h2) with respect to a respective lower edge (28) of their respective profile rails (12, 14) and the support elements (32, 34) are arranged on the support arm (22) with lower elevation (h1).

10. The solar module arrangement according to claim 9, wherein the profile rails are mounted so that their support surfaces (24) are at identical elevations (24) with respect to the respective profile rails in a common plane.

11. The solar module arrangement according to claim 10, wherein the support elements (32, 34, 36) on the support arms (22) with lower elevation (h1) respectively include a support surface (44) for a frame (R1) of a solar module, wherein the support surface is in the common plane of the support surfaces (24) with greater elevation (h2).

12. The solar module arrangement according to claim 10, wherein the common plane of the support surfaces (24, 44) is inclined relative to a horizontal plane (H) at the installation location of the solar module arrangement, wherein the horizontal plane (H) is arranged perpendicular to a vertical direction (L) at the installation location oriented towards the center of the earth.

13. The solar module arrangement according to claim 8, wherein the frames (R1, R2) of the solar modules are rectangular with two longer sides and two shorter sides, wherein the two longer sides are entirely supported on profile rails (12, 14, 16) and the two shorter sides extend between two adjacent profile rails (12, 14; 14, 16).

14. The solar module arrangement according to claim 12, wherein the support elements (36) are attached at an upper most profile rail (16) of the solar module arrangement, wherein the upper most profile rail is the farthest away from the horizontal plane.
